(19) United States
(12) Patent Application Publication
(10) Pub. No.: US 2012/0217056 A1
(43) Pub. Date: Aug. 30, 2012

(54) Electronic Component and Package for Device, and Method of Manufacturing the Same

(75) Inventor: Keiji Horikawa, Nagaokakyo-shi (JP)

(73) Assignee: MURATA MANUFACTURING CO., LTD., Nagaokakyo-shi (JP)

(21) Appl. No.: 13/463,209

(22) Filed: May 3, 2012

Related U.S. Application Data
(63) Continuation of application No. PCT/JP2010/067366, filed on Oct. 4, 2010.

(30) Foreign Application Priority Data
Nov. 11, 2009 (JP) 2009-257901

(51) Int. Cl. H01L 23/08; H05K 3/30

(52) U.S. Cl. 174/565; 29/832

(57) ABSTRACT

An electronic component provided with a device and a package storing the device. The package includes a ceramic base, a lid, and a connecting member connecting the ceramic base and the lid. A portion of the lid that joins with the connecting member is made of a metal. The connecting member is made of a metal mainly containing aluminum, and is directly joined to the ceramic base. The device is fixed to one of the ceramic base and the lid.

### CROSS REFERENCE TO RELATED APPLICATIONS

The present application is a continuation of International application No. PCT/JP2010/067366, filed Oct. 4, 2010, which claims priority to Japanese Patent Application No. 2009-257901, filed Nov. 11, 2009, the entire contents of each of which are incorporated herein by reference.

### FIELD OF THE INVENTION

The present invention relates to an electronic component and a package for device that are highly airtight, and a method of manufacturing such a component and a package.

### BACKGROUND OF THE INVENTION

As electronic devices have become smaller and thinner, there is an increasing demand for electronic components such as electric double layer capacitors, batteries, and piezoelectric devices to be smaller and thinner. Many of such commonly used electronic components are of a surface mount type suitable for being mounted on a circuit board. Surface mount electronic components are often configured such that a device is stored within a package provided by joining a metallic lid body to a base material formed by an insulating material such as ceramic using a connecting member. Patent document 1 discloses a structure of a battery as shown in FIG. 7.

A battery 180 illustrated in FIG. 7 includes a device, a package in which the device is stored, and an electrolysis solution.

The following describes a structure of the package for the device. A ceramic base material 110 made of aluminum oxide includes a recess at a central portion of its upper surface, and a stepped portion 110a is provided between an inner surface and a bottom surface of the recess. The bottom surface of the recess is provided with an internal electrode 122a, and an upper surface of the stepped portion 110a is provided with an internal electrode 122b. Further, external electrodes 124a and 124b are provided on an external bottom surface of the ceramic base material 110. A connecting electrode 123a is provided extending between the internal electrode 122a and the external electrode 124a, and a connecting electrode 123b is provided extending between the internal electrode 122b and the external electrode 124b. These electrodes are constituted by tungsten.

Further, a metallic foundation layer 128a made of tungsten is joined to the upper surface of the ceramic base material 110 so as to surround the recess. The metallic foundation layer 128a is covered by nickel plating 128b, thereby providing a foundation layer 128.

Further, a frame-shaped member 126 having an aluminum layer provided over a surface of an iron-nickel-cobalt alloy is brazed to the foundation layer 128 by aluminum brazing fillers 125 and 127 so as to surround the recess of the ceramic base material 110. The aluminum brazing filler 127 is provided so as to cover a surface of the foundation layer 128.

The foundation layer 128 improves wettability between the upper surface of the ceramic base material 110 and the aluminum brazing filler 127, and thus the connection strength between the ceramic base material 110 and the frame-shaped member 126 becomes more robust.

Further, a lid body 150 made of aluminum is brazed onto the frame-shaped member 126 by an aluminum brazing filler 125.

The package stores a device 140. The device 140 is provided such that a plate-shaped positive electrode 141 containing LiCoO₂ and acetylene black and a plate-shaped negative electrode 142 containing cokes are layered with a separator 143 of a non-woven cloth of polyolefin fiber interposed therebetween. As the positive electrode 141 is connected to the internal electrode 122a, and the negative electrode 142 is connected to the internal electrode 122b, the device 140 is fixed within the recess of the ceramic base material 110.

Further, in the package, an electrolysis solution 170 in which lithium tetrafluoroborate is dissolved in dimethoxyethane as an organic solvent is filled.

The airtightly sealed battery 180 is thus configured.

Patent Document 1: Japanese Unexamined Patent Application Publication No. 2005-63942

### SUMMARY OF THE INVENTION

However, the above conventional technique poses a problem that in use of or in the process of manufacturing the battery 180, the electrolysis solution 170 is brought into contact with the foundation layer 128 when microcracks occur in the aluminum layer made of the aluminum brazing filler 127. When the electrolysis solution 170 is brought into contact with the foundation layer 128, the foundation layer 128 becomes corroded, and airtightness of the battery 180 is reduced. Such contact may occur when the surface of the foundation layer 128 is not sufficiently covered with the aluminum brazing filler 127, or when the aluminum brazing filler 127 is alloyed with the metal in the foundation layer 128 in brazing, causing the metal in the foundation layer 128 to be exposed on the surface of the aluminum brazing filler 127.

Further, when such alloying occurs, the strength at the joining portion may considerably decrease.

Moreover, there is also a problem of poor productivity, since the aluminum brazing fillers 125 and 127, the frame-shaped member 126, and the foundation layer 128 are required, the manufacturing process becomes cumbersome, and a great deal of time and effort is required in order to join the ceramic base material 110 with the lid body 150.

Thus, an object of the present invention is to provide an electronic component and a package therefor that are highly airtight, as well as a method of manufacturing such a component and a package with a simplified process and improved productivity.

In order to solve the above problems, an electronic component of the present invention includes: a device; and a package storing the device, wherein the package includes a ceramic base material, a lid body, and a connecting member connecting the ceramic base material and the lid body, a joining portion of the lid body with the connecting member is made of a metal, the connecting member is made of a metal mainly containing aluminum, and directly joined to the ceramic base material, and the device is fixed to one of the ceramic base material and the lid body.

In the electronic component of the present invention, the connecting member is preferably made of a metal containing no less than 86 wt % aluminum.

In the electronic component of the present invention, the joining portion of the lid body with the connecting member is preferably made of a metal mainly containing aluminum.

In the electronic component of the present invention, the lid body preferably includes a recess capable of storing the device.

In the electronic component of the present invention, the package is preferably filled with an electrolysis solution.

A package for storing a device according to the preferred embodiment of present invention includes: a ceramic base material; a lid body; and a connecting member connecting the ceramic base material and the lid body, wherein a joining portion of the lid body with the connecting member is made of a metal, and the connecting member is made of a metal mainly containing aluminum, and directly joined to the ceramic base material.

According to the present invention, there is also provided a method of manufacturing an electronic component provided with a device and a package for storing the device, the package including a ceramic base material and a lid body, the method including: a step of preparing the device, the ceramic base material, and the lid body having a joining portion made of a metal; a step of forming a connecting member on a surface of the ceramic base material, the connecting member being made of a metal mainly containing aluminum; a step of fixing the device to one of the ceramic base material and the lid body; and a step of joining the joining portion of the lid body to the connecting member to form the package.

In the method of manufacturing an electronic component of the present invention, the step of forming the connecting member preferably includes: a step of preparing a molten metal mainly containing aluminum; a step of forming a metallic layer on the surface of the ceramic base material by applying the molten metal to the ceramic base material and then solidifying the molten metal; and a step of patterning the metallic layer, thereby forming the connecting member.

The method of manufacturing an electronic component of the present invention further preferably includes, after the step of forming the metallic layer, a step of patterning the metallic layer and forming an internal electrode for fixing the device.

In the method of manufacturing an electronic component of the present invention, the connecting member is preferably made of a metal containing no less than 86 wt % aluminum.

In the method of manufacturing an electronic component of the present invention, the joining portion of the lid body is preferably made of a metal mainly containing aluminum.

In the method of manufacturing an electronic component of the present invention, the lid body preferably includes a recess capable of storing the device.

In the method of manufacturing an electronic component of the present invention, the step of joining the lid body to the connecting member is preferably performed by laser welding.

The method of manufacturing an electronic component of the present invention further preferably includes a step of filling the package with an electrolysis solution.

According to the present invention, there is provided a method of manufacturing a package for storing a device, the method including: a step of preparing a ceramic base material and a lid body having a joining portion made of a metal; a step of forming a connecting member on a surface of the ceramic base material, the connecting member being made of a metal mainly containing aluminum; and a step of joining the joining portion of the lid body to the connecting member.

As described above, according to the electronic component and the package of the present invention, the connecting member connecting the ceramic base material and the lid body is made of a metal mainly containing aluminum, thereby providing high strength and a high corrosive resistance to an electrolyte. This allows the electronic component and the package for device of the present invention to be highly airtight.

Further, as a foundation layer or the like is not necessary for the connecting member, it is possible to simplify the process and to improve productivity.

### BRIEF EXPLANATION OF THE DRAWINGS

FIGS. 1(A) to 1(C) are schematic diagrams for describing a process of forming a metallic layer on a surface of a ceramic base material according to an embodiment of the present invention.

FIGS. 2(A) and 2(B) are schematic diagrams illustrating a configuration of a substrate according to the embodiment of the present invention.

FIGS. 3(A) and 3(B) are schematic diagrams for describing a process of fixing a device to the ceramic base material according to the embodiment of the present invention.

FIGS. 4(A) and 4(B) are schematic diagrams for describing a method of manufacturing an electronic component and a configuration thereof according to the embodiment of the present invention.

FIG. 5 is a schematic diagram for describing a method of manufacturing an electronic component according to a modified example of the present invention.

FIGS. 6(A) and 6(B) are schematic diagrams for describing a method of manufacturing an electronic component according to another modified example of the present invention.

FIG. 7 is a schematic diagram for describing a configuration of a conventional electronic component.

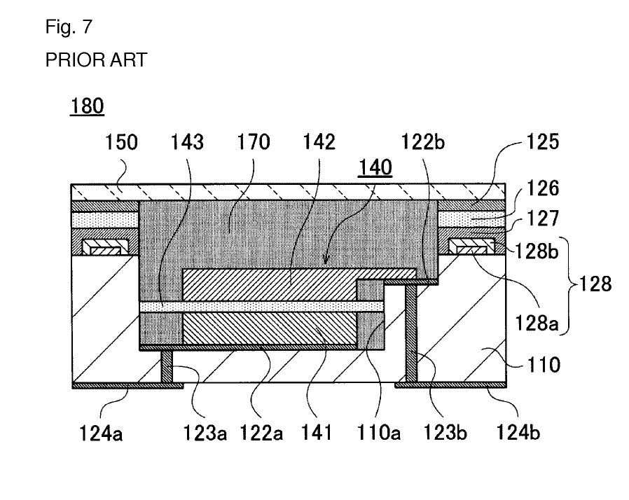

### DETAILED DESCRIPTION OF THE PREFERRED EMBODIMENTS OF THE INVENTION

Hereinafter, an embodiment of the present invention will be described with reference to the drawings.

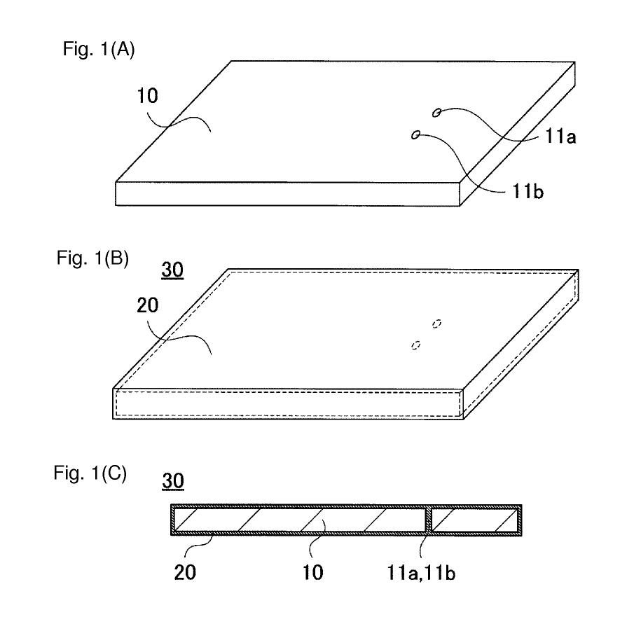

FIG. 1 is a schematic diagram for describing a process of forming a metallic layer on a surface of a ceramic base material according to an embodiment of the present invention.

First, as illustrated in FIG. 1(A), a ceramic base material 10 having through holes 11a and 11b and made of alumina is prepared as a base material.

Next, a metal of a desired composition mainly containing aluminum is set in a crucible, and then melted by heating the crucible using a heater in a nitrogen gas atmosphere, and whereby a molten metal is prepared. In this embodiment, a metal containing 99 wt % aluminum is used as the metal mainly containing aluminum.

Subsequently, the ceramic base material 10 is dipped in the molten metal. This allows the molten metal to be attached to the surface of the ceramic base material 10. At this time, the molten metal also flows into and fills the through holes 11a and 11b. Thereafter, the ceramic base material 10 is taken out of the molten metal in a nitrogen atmosphere, and the molten metal attached to the surface is gradually cooled and solidified to be joined to the surface of the ceramic base material 10. Accordingly, as illustrated in FIG. 1(B) and FIG. 1(C), a combined member 30 having a metallic layer 20 of aluminum on the surface of the ceramic base material 10 and within the through holes 11a and 11b is obtained. In such joining between a ceramic and a metal using a molten metal, the metal and the ceramic become highly lattice-matched to each other as the metal goes through a process of gradual cooling from a state of the molten metal, thereby making connection strength more robust.

Subsequently, a surface of the combined member 30 is ground using a grinding machine, making a surface of the metallic layer 20 even.

Next, a process of forming a connecting member, internal electrodes, and the like by patterning the metallic layer will be described.

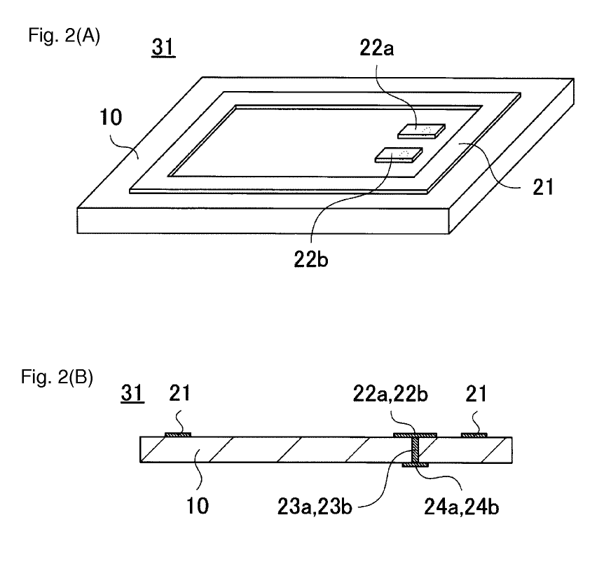

First, a photoresist film is formed on the surface of the metallic layer 20, the metallic layer 20 is covered with a light shielding pattern mask and subjected to exposure. Then, a development process is performed to remove a light-shielded part of the photoresist film. Next, patterning is performed by dissolving a portion of the metallic layer 20, excluding the masked portion of the metallic layer 20 on which the photoresist film is deposited, in a ferric chloride-hydrochloric acid mixed etching solution. Accordingly, as illustrated in FIGS. 2(A) and 2(B), a substrate 31 having internal electrodes 22a and 22b, external electrodes 24a and 24b, and a connecting member 21 on the surface of the ceramic base material 10 is obtained.

The connecting member 21 is provided in a frame shape so as to surround the internal electrodes 22a and 22b.

Further, the internal electrode 22a and the external electrode 24a are electrically connected via a connecting electrode 23a configured by the metallic layer 20 provided within the through hole 11a.

Further, the internal electrode 22b and the external electrode 24b are electrically connected via a connecting electrode 23b configured by the metallic layer 20 provided within the through hole 11b.

Plating is provided on surfaces of the external electrodes 24a and 24b so as to improve wettability with solders. According to this embodiment, the metallic layer is sequentially deposited on the surfaces of the external electrodes 24a and 24b using nickel plating and gold plating.

In this manner, the internal electrodes, the external electrodes, and the connecting electrodes are formed at the same time as the connecting member by patterning the metallic layer provided by the molten metal, and therefore the process is simplified and the productivity is improved as compared to the case in which these electrodes are formed in separate steps.

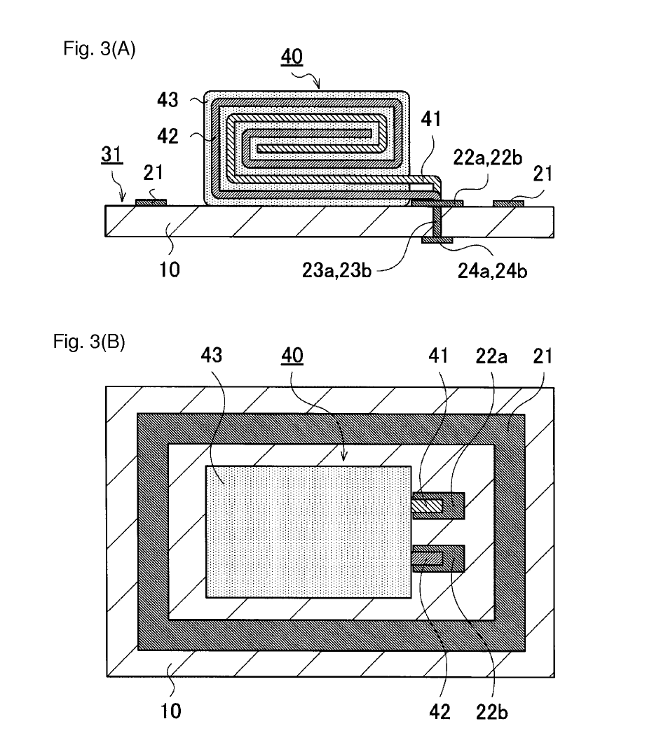

Next, a process for fixing a device to the ceramic base material will be described with reference to FIGS. 3(A) and 3(B).

A device 40 is formed by having a positive electrode 41 and a negative electrode 42 wound about each other with an insulating separator 43 interposed therebetween. An electrode configured such that a polarized electrode layer containing active carbon is supported on a surface of a sheet-shaped current collector made of aluminum is used for the positive electrode 41 and the negative electrode 42.

One end of the positive electrode 41 is connected and fixed to the internal electrode 22a provided on the surface of the ceramic base material 10 by ultrasonic welding. One end of the negative electrode 42 is connected and fixed to the internal electrode 22b provided on the surface of the ceramic base material 10 by ultrasonic welding. The electrodes may be connected by, not limited to the ultrasonic welding, laser welding or TIG welding.

Next, a process of forming a package for the device by joining a joining portion of a lid body to the connecting member will be described.

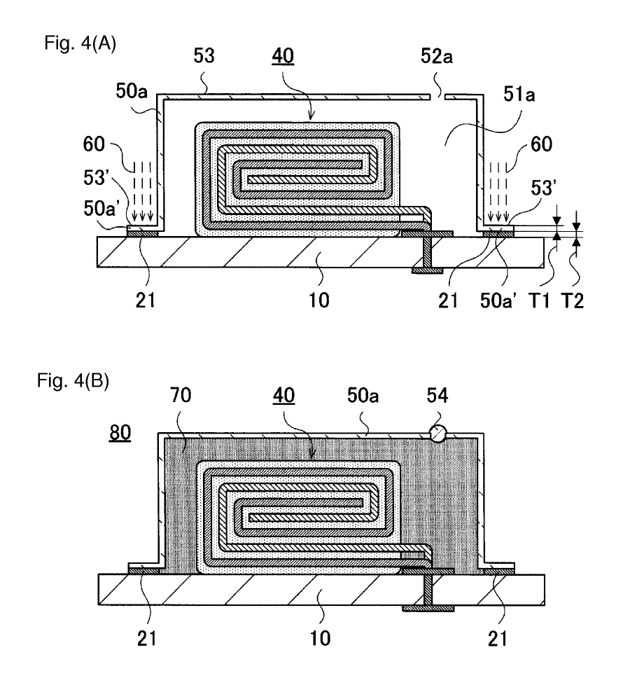

First, as illustrated in FIG. 4(A), a lid body 50a having a recess 51a capable of storing the device 40 and a through hole 52a, and made of a metal containing 99 wt % aluminum is prepared. An end portion 50a′ positioned at an edge of the lid body 50a extends outwardly, that is, toward an opposite side of the recess 51a.

The package to store the device 40 can be obtained by joining the end portion 50a′ of the lid body 50a to the connecting member 21 provided on the surface of the ceramic base material 10 by laser welding.

While other joining method such as resistance welding or ultrasonic welding may be used, it is preferable to use laser welding. The laser welding is performed by irradiating a surface 53′ of the end portion 50a′ with a laser beam 60, the surface 53′ being the surface on the side opposite from a contacting surface with the connecting member 21. Since the use of laser welding allows partial welding of a very small area as compared to other joining methods, it is possible to reduce uneven welding and defective sealing, and there is less possibility that a portion around the joining portion of the ceramic base material 10 be damaged due to heat. Further, since it is not necessary to strongly press a welded portion as in resistance welding, it is possible to reduce occurrence of damage or deformation of the ceramic base material, the lid body, or the connecting member. Moreover, since a joining width can be easily set, it is possible to accommodate the electronic components of various sizes, as well as downsizing of the electronic components. Connection strength can also be easily designed by changing the joining width. In addition, as compared to ultrasonic welding, it is possible to reduce spatter generation in the welding, and to suppress occurrence of short circuit associated therewith.

When performing laser welding, it is preferable that a thickness T2 of the connecting member 21 be thicker than a thickness T1 of the end portion 50a′. In this manner, it is possible to provide more robust joining by welding with smaller laser energy.

It is preferable that the connecting member 21 contain no less than 86 wt % aluminum, and more preferably, no less than 99 wt %. If a contained amount of metals other than aluminum is large, alloying can easily occur when welding, and the strength of the connecting member may considerably decrease. This may also result in uneven connection such as uneven welding due to different melting points among metals, possibly leading to occurrence of defective sealing.

Next, a process of filling an electrolysis solution into the package and sealing the package will be described.

As illustrated in FIG. 4(B), an electrolysis solution 70 is filled into the package through the hole 52a. For the electrolysis solution 70, TEMA-BF₄ (triethylmethylammonium tetrafluoroborate) is used as an electrolyte, and PC (propylene carbonate) as an organic solvent.

Then, a metal ball 54 made of aluminum is provided so as to block the hole 52a and welded to the lid body 50a by laser welding, and whereby the package for the device is airtightly sealed.

In this manner, an electric double layer capacitor 80 can be obtained.

As described above, according to this embodiment, the metal mainly containing aluminum that is highly corrosive-resistant is used as the connecting member, and it is not necessary to provide a foundation layer of a metal having a low corrosive resistance to an electrolysis solution. Therefore, the connecting member may not be corroded due to contact with the electrolysis solution, and it is possible to ensure high airtightness for the package for device. Additionally, reduction of the strength may not occur due to alloying with metals used for the foundation layer.

Further, while tungsten or nickel is commonly used as the foundation layer, since a foundation layer is not necessary in this embodiment, it is possible to reduce cost of raw materials, to simplify the process, and to improve productivity.

Moreover, since the internal electrodes are formed by the same material as the connecting member, a high corrosive resistance to the electrolysis solution can be obtained.

Furthermore, since the joining portion between the lid body and the connecting member of the lid body are also constituted by the metal mainly containing aluminum, a high corrosive resistance to the electrolysis solution can be obtained.

Further, according to this embodiment, the electric double layer capacitor has been described as an example of the electronic component. However, the present invention is not limited thereto, and can be applied to electronic components having a device stored in a package for device, such as batteries and piezoelectric devices.

According to this embodiment, alumina is used as the ceramic base material 10, but the present invention is not limited thereto, and aluminum nitride may be used, for example. While aluminum nitride is more expensive than alumina as the material, aluminum nitride also provides high heat conductivity and superior heat dissipation performance.

Further, according to this embodiment, in order to improve external appearance, to increase strength, and to suppress heat expansion, a clad layer may be provided over an outer surface 53 of the lid body 50a by cladding a metal of a material different from that of the lid body 50a such as SUS, kovar, or 42% Ni—Fe alloy. In this case, it is preferable that the thickness T1 of the end portion 50a′ at a layer mainly containing aluminum be no smaller than 10 μm, in order to prevent the connecting member 21 and the clad layer from alloying due to heat generated from welding when laser welding the end portion 50a′ of the lid body 50a to the connecting member 21 provided on the surface of the ceramic base material 10.

Moreover, according to this embodiment, an aluminum-silicon-based alloy containing 4.5 wt % to 14 wt % silicon may be used as the connecting member 21. A heat expansion coefficient of this alloy is similar to that of the ceramic base material. Therefore, when using this alloy as the connecting member, a thermal stress due to a difference between the heat expansion ratios of the ceramic base material and the connecting member becomes smaller, thereby suppressing occurrence of cracks and such and improving airtightness of the package for device. Examples of such an alloy include A4043 (containing 4.5 wt % to 6.0 wt % silicon) and A4032 (containing 11.0 wt % to 13.5 wt % silicon) provided by Japanese Industrial Standards.

Furthermore, according to this embodiment, the lid body 50a made of a metal containing 99 wt % aluminum is used. However, the lid body may be configured such that the joining portion of the lid body with the connecting member is made of a metal mainly containing aluminum. It is more preferable that the joining portion contain no less than 86 wt % aluminum.

Further, the lid body having the recess may be formed such that only the joining portion is made of a metal mainly containing aluminum, and such that a portion other than the joining portion is made of ceramic. Additionally, the recess may be provided for the ceramic base material. However, it is preferable that a side wall of the package for device configured by the ceramic base material and the lid body be made of a metal. In this case, the side wall can easily absorb and alleviate a thermal stress due to a difference between the heat expansion ratios of the ceramic base material and the lid body. Therefore, it is less likely that cracks and the like occur in the side wall or deterioration of airtightness of the package for device may occur.

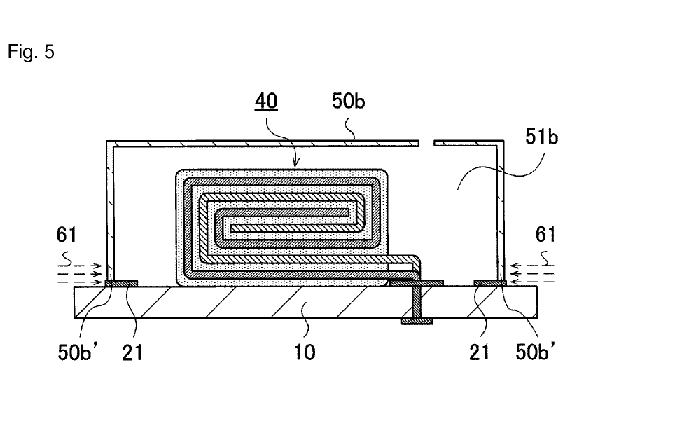

Moreover, according to this embodiment, the welding of the lid body is performed by irradiating the surface of the lid body with a laser beam. However, as in a modified example illustrated in FIG. 5, the welding may be performed by irradiating an interface between a lid body 50b and the connecting member 21 with a laser beam 61. The lid body 50b has a recess 51b in which the device 40 can be stored, and an end portion 50b′ at an edge is not bent.

In this case, it is preferable to make the connecting member 21 thicker, in order to prevent the ceramic base material 10 from being erroneously irradiated with the laser beam 61. Moreover, according to this modified example, the end portion 50b′ may be bent outwardly, that is, toward an opposite side of the recess 51b. However, when the end portion 50b′ is not bent, it is possible to increase an internal volume of the package for device.

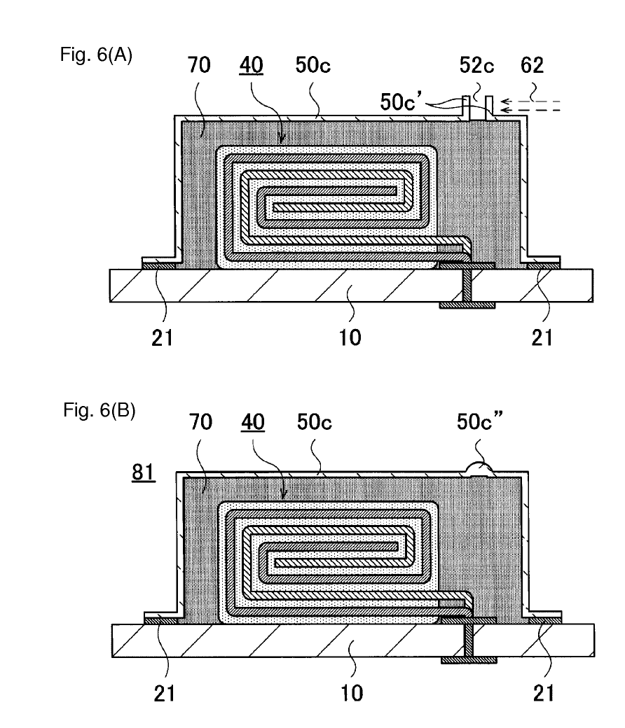

Furthermore, according to this embodiment, the metal ball has been used in order to block the hole in the lid body. However, as in a modified example illustrated in FIG. 6, it is possible to use a lid body 50c having a projecting portion 50c′ that projects outwardly from a circumference of a hole 52c. In this case, as illustrated in FIG. 6(A), the projecting portion 50c′ is irradiated with a laser beam 62 after the electrolysis solution 70 is filled into the package for device through the hole 52c. Accordingly, the projecting portion 50c′ is melted, and then cooled to provide a stopper 50c″ blocking the hole 52c as illustrated in FIG. 6(B), whereby the package for device is airtightly sealed. In this manner, an electric double layer capacitor 81 can be obtained.

It should be noted that, in FIG. 5 and FIG. 6, like components illustrated in FIG. 1 to FIG. 4 are denoted by like reference numerals.

### DESCRIPTION OF REFERENCE SYMBOLS

10, 110 ceramic base material

11a, 11b through hole

20 metallic layer

21 connecting member

22a, 22b, 122a, 122b internal electrode

23a, 23b, 123a, 123b connecting electrode

24a, 24b, 124a, 124b external electrode

30 combined member

31 substrate

40, 140 device

41, 141 positive electrode

42, 142 negative electrode

43, 143 separator

50a, 50b, 50c, 150 lid body

50a′, 50b′ end portion

50c′ projecting portion

50c″ stopper

51a, 51b recess

52a, 52c hole

53, 53′ surface

54 metal ball

60, 61, 62 laser beam

70, 170 electrolysis solution

80, 81 electric double layer capacitor

110a stepped portion

125, 127 aluminum brazing filler

126 frame-shaped member

128 foundation layer

128a metallic foundation layer

128b plating

180 battery

T1, T2 thickness

1. An electronic component comprising:
a device; and
a package storing the device, the package including:
a ceramic base, a lid, and a connecting member connecting the ceramic base and the lid, wherein
a portion of the lid that joins with the connecting member is a first metal,
the connecting member is a second metal mainly containing aluminum, and directly joined to the ceramic base, and
the device is fixed to one of the ceramic base and the lid.

2. The electronic component according to claim 1, wherein the second metal contains no less than 86 wt % aluminum.

3. The electronic component according to claim 1, wherein the second metal contains no less than 99 wt % aluminum.

4. The electronic component according to claim 1, wherein the first metal mainly contains aluminum.

5. The electronic component according to claim 1, wherein the lid includes a recess configured to store the device.

6. The electronic component according to claim 1, further comprising an electrolysis solution within the package.

7. A package for storing a device, the package comprising:
a ceramic base;
a lid; and
a connecting member connecting the ceramic base and the lid, wherein
a portion of the lid body that joins with the connecting member is a first metal, and
the connecting member is a second metal mainly containing aluminum, and directly joined to the ceramic base.

8. The package according to claim 7, wherein the second metal contains no less than 86 wt % aluminum.

9. The package according to claim 7, wherein the second metal contains no less than 99 wt % aluminum.

10. The package according to claim 9, wherein the first metal mainly contains aluminum.

11. A method of manufacturing an electronic component provided with a device and a package for storing the device, the package including a ceramic base and a lid, the method comprising:
forming a connecting member on a surface of the ceramic base, the connecting member being made of a first metal mainly containing aluminum;
fixing the device to one of the ceramic base and the lid; and
joining a portion of the lid to the connecting member to form the package, the portion of the lid being made of a second metal.

12. The method of manufacturing an electronic component according to claim 11, wherein
the step of forming the connecting member includes:
preparing a molten metal mainly containing aluminum;
forming a metallic layer on a surface of the ceramic base by applying the molten metal to the ceramic base and then solidifying the molten metal; and
patterning the metallic layer, thereby forming the connecting member.

13. The method of manufacturing an electronic component according to claim 12, further comprising:
after the step of forming the metallic layer, patterning the metallic layer and forming an internal electrode.

14. The method of manufacturing an electronic component according to claim 11, wherein the first metal contains no less than 86 wt % aluminum.

15. The method of manufacturing an electronic component according to claim 11, wherein the second metal mainly contains aluminum.

16. The method of manufacturing an electronic component according to claim 11, wherein the lid includes a recess configured to store the device.

17. The method of manufacturing an electronic component according to claim 11, wherein the step of joining the portion of the lid to the connecting member is performed by laser welding.

18. The method of manufacturing an electronic component according to claim 11, further comprising:
filling the package with an electrolysis solution.

19. A method of manufacturing a package for storing a device, the method comprising:
forming a connecting member on a surface of a ceramic base, wherein the connecting member is a first metal mainly containing aluminum; and
joining a portion of the lid to the connecting member, the portion of the lid being made of a second metal.

20. The method of manufacturing a package according to claim 19, wherein the first metal contains no less than 86 wt % aluminum.
